(19) United States
(12) Patent Application Publication
(10) Pub. No.: US 2026/0130106 A1
(43) Pub. Date: May 7, 2026

(54) PHOTOELECTRIC DEVICE AND PREPARATION METHOD THEREFOR

(71) Applicant: TCL Technology Group Corporation, Huizhou, Guangdong (CN)

(72) Inventor: Wenlin LIANG, Huizhou, Guangdong (CN)

(73) Assignee: TCL Technology Group Corporation, Huizhou, Guangdong (CN)

(21) Appl. No.: 19/114,431

(22) PCT Filed: Sep. 20, 2023
(86) PCT No.: PCT/CN2023/120174

§ 371 Date: Mar. 21, 2025

(30) Foreign Application Priority Data
Sep. 28, 2022 (CN) 202211193590.5

(51) Int. Cl. H10K 85/30; C09K 11/88; C09K 113/00; H10K 50/15; H10K 50/17; H10K 71/12; H10K 85/10; H10K 85/20; H10K 85/60

(52) U.S. Cl. CPC H10K 85/381; C09K 11/883; H10K 71/12; H10K 85/1135; H10K 85/146; H10K 85/151; H10K 85/211; H10K 85/654; C09K 2113/00; H10K 50/15; H10K 50/17

(57) ABSTRACT

The present disclosure discloses a photoelectric device and a preparation method therefor. The photoelectric device includes a cathode; an anode; and a functional layer, located between the cathode the anode; wherein the functional layer includes an electronic functional layer, and a material of the electronic functional layer includes an electronic functional material crosslinked by a crosslinking agent, and the crosslinking agent includes an azide compound which has at least two azide groups as terminal groups. The electronic functional layer of the photoelectric device provided by the present disclosure has good stability.

The present disclosure claims priority to Chinese Application NO. 202211193590.5 filed in the China National Intellectual Property Administration on Sep. 28, 2022 and entitled “PHOTOELECTRIC DEVICE AND PREPARATION METHOD THEREFOR”, the content of which is incorporated herein by reference in its entirety.

### TECHNICAL FIELD

The present disclosure relates to a field of optoelectronics, and more particularly, to photoelectric device and preparation method therefor.

### BACKGROUND

Photoelectric device includes light emitting diodes, solar cells, and photodetectors, etc. Photoelectric device generally includes a cathode, an anode and a functional layer. Electron transport layer is an important functional layer in photoelectric device, and solution method is one of the common methods to prepare electron transport layer in photoelectric device. However, in the prior art, the electron transport layer has the problem of poor stability. Specifically, when another functional layer is prepared on the prepared electron transport layer by the solution method, the prepared electron transport layer may be destroyed by the solvent of the solution used to prepare the functional layer, resulting in the reduction or even failure of the effect of the prepared electron transport layer. At the same time, after the prepared electron transport layer is damaged by the solvent, its film surface is uneven, which is not conducive to the preparation of the functional layer to be prepared.

### Technical Solution

In view of this, the present disclosure provides a photoelectric device and a preparation method therefor.

The present disclosure provides a photoelectric device. The photoelectric device includes a cathode; an anode; and a functional layer, located between the cathode the anode; wherein the functional layer includes an electronic functional layer, and a material of the electronic functional layer includes an electronic functional material crosslinked by a crosslinking agent, and the crosslinking agent includes an azide compound which has at least two azide groups as terminal groups.

Alternatively, a general formula of the azide compound is N₃—R₂—R₁—R₃—N₃, wherein R₁ is a linking group which is selected from one or more of substituted or unsubstituted —(CH₂)ₘ₁—, —(CH₂)ₘ₂CH═CH(CH₂)ₘ₃—, —(CH₂)ₘ₄C≡C(CH₂)ₘ₅—, —(CH₂)ₘ₆O(CH₂)ₘ₇—, —(CH₂)ₘ₈CO(CH₂)ₘ₉—, —(CH₂)ₘ₁₀NHCO(CH₂)ₘ₁₁—, —(CH₂)ₘ₁₂CONH(CH₂)ₘ₁₃—, —(CH₂)ₘ₁₄OCO(CH₂)ₘ₁₅—, —(CH₂)ₘ₁₆COO(CH₂)ₘ₁₇—, —(CH₂)ₘ₁₈(OCH₂)ₘ₁₉— and —COO(CH₂)ₘ₂₀OOC—, and m₁-m₂₀ are independently selected from an integer of 1-20.

R₂ and R₃ are independently selected from one of substituted or unsubstituted aromatic ring and substituted or unsubstituted heteroaromatic ring, wherein the heteroaromatic ring includes at least one heteroatom, and the heteroatom is selected from one or more of N, O and S; ring atoms of the aromatic ring include 6-30 C atoms, and ring atoms of the heteroaromatic ring include 1-25 C atoms.

Alternatively, m₁-m₂₀ are each independently selected from an integer of 1-10.

Alternatively, R₁ is selected from one of —(CH₂)ₙ—, —CH₂CH═CH—, —CH₂C≡C—, —CH₂OCH₂—, —CH₂COCH₂—, —CH₂NHCOCH₂—, —CH₂OCOCH₂—, wherein a value range of n is 1-3.

Alternatively, the aromatic ring is selected from one of benzene ring, naphthalene ring, anthracene ring and phenanthrene ring.

The heteroaromatic ring is selected from one or more of thiophene ring, benzothiophene ring, isobenzothiophene ring, dibenzothiophene ring, pyrrole ring, indole ring, isoindole ring, pyridine ring, quinoline ring, benzo-5,6-quinoline ring, benzo-6,7-quinoline ring, benzo-7,8-quinoline ring, isoquinoline ring, acridine ring, phenazine ring, phenothiazine ring, phenazine ring, pyrazine ring, indazine ring, pyridazine ring, benzopyridazine ring, 1,3,5-triazine ring, 1,2,4-triazine ring, 1,2,3-triazine ring, 1,2,4,5-tetrazine ring, 1,2,3,4-tetrazine ring, 1,2,3,5-tetrazine ring, carbazole ring, azacarbazole ring, benzocarboline ring, pyrazole ring, indazole ring, oxazole ring, isoxazole ring, imidazole ring, benzimidazole ring, naphthoxazoline ring, phenimidazole ring, pyridoimidazole ring, pyrazinimidazole ring, quinoxaline imidazole ring, 1,2,3-triazole ring, 1,2,4-triazole ring, tetrazole ring, isoxazole ring, benzotriazole ring, 1,2,3-oxadiazole ring, 1,2,4-oxadiazole ring, 1,2,5-oxadiazole ring, 1,3,4-oxadiazole ring, benzoxazole ring, naphthoxazole ring, anthracazole ring, phenazole ring, 1,2-thiazole ring, 1,3-thiazole ring, benzothiazole ring, 1,2,3-thiadiazole ring, 1,2,4-thiadiazole ring, 1,2,5-thiadiazole ring, 1,3,4-thiadiazole ring, benzothiadiazole ring, pyrimidine ring, benzopyrimidine ring, naphthyridine ring, pteridine ring, quinoxaline ring, phenanthroline ring and purine ring.

Alternatively, a general formula of the azide compound is N₃—R₄—N₃, and R₄ is selected from one of substituted or unsubstituted saturated hydrocarbon groups with 2-30 C atoms and substituted or unsubstituted unsaturated hydrocarbon groups with 4-30 C atoms.

A substituent of R₄ is selected from one or more of nitro, cyano, carboxyl, halogen atom, hydroxyl, phenyl, vinyl, C1-C10 alkyl, C1-C10 alkoxy and C1-C10 alkylthio.

Alternatively, R₄ is selected from one of substituted or unsubstituted saturated hydrocarbon groups with 6-30 C atoms and substituted or unsubstituted unsaturated hydrocarbon groups with 6-30 C atoms.

Alternatively, R₄ is selected from one of —(CH₂)ₙ₁—, —(CH₂)ₙ₂CH═CH(CH₂)ₙ₃—, wherein n₁-n₃ are independently selected from an integer of 6-20.

Alternatively, the azide compound is selected from one or more compound having the following structural formula:

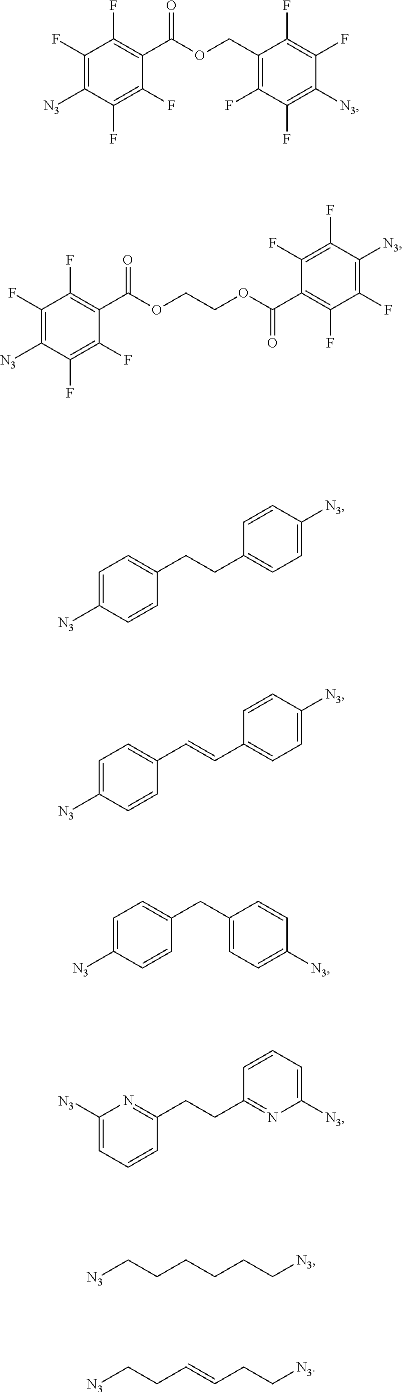

Alternatively, a surface of the electronic functional material is connected with a ligand, and the crosslinking agent crosslinks the electronic functional material through the ligand; and the ligand is selected from one or more of substituted or unsubstituted alcohol with 1-20 C atoms, substituted or unsubstituted mercaptan with 1-20 C atoms, substituted or unsubstituted carboxylic acid with 1-20 C atoms, substituted or unsubstituted phosphonic acid with 1-20 C atoms, and substituted or unsubstituted amines with 1-20 C atoms.

A substituent of the substituted ligand is selected from one or more of nitro, cyano, carboxyl, halogen atom, hydroxyl, phenyl, vinyl, C1-C10 alkyl, C1-C10 alkoxy and C1-C10 alkylthio.

Alternatively, the electronic functional layer includes a first film layer and a second film layer, and the second film layer is arranged on the side of the first film layer far away from the cathode

A material of the first film layer includes a first electronic functional material crosslinked by a first crosslinking agent, and the first electronic functional material is a doped metal oxide, and a doping element of the first electronic functional material is selected from one or more of Ga, Li, Al, Ag, In and Cd; a material of the second film layer includes a second electronic functional material crosslinked by a second crosslinking agent, and the second electronic functional material is a doped or undoped metal oxide, and a doping element of the second electronic functional material is selected from one or more of Mg and halogen elements.

The first crosslinking agent and the second crosslinking agent each independently include an azide compound which has at least two azide groups as terminal groups.

Alternatively, a material of the second film layer also includes an auxiliary electronic functional material, and the auxiliary electronic functional material is selected from one or more of graphene, C60 and MoS₂.

Alternatively, a mass ratio of the first crosslinking agent in the material of the first film layer is 1%-10%.

A mass ratio of the second crosslinking agent in the material of the second film layer is 1%-10%.

Alternatively, the functional layer also includes a hole functional layer and a luminescent layer; the hole functional layer includes a hole transport layer and/or a hole injection layer; the hole functional layer is disposed between the anode and the luminescent layer, and the luminescent layer is disposed between the hole functional layer and the electronic functional layer, and the electronic functional layer is disposed between the luminescent layer and the cathode.

A material of the cathode is selected from one or more of metallic material, carbon-silicon material and metal oxide.

A material of the luminescent layer is selected from one or more of Si, Ge, CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, CdZnSeSTe, CdSe/ZnS, CdZnSe/ZnS, CdS/CdZnS, InP, InAs, InAsP, InP/InAsP, PbS, PbSe, PbTe, PbSeS, PbSeTe, PbSTe, PbSe/PbS, GaN.

A material of the hole transport layer is selected from organic material with hole transport capability, and is specifically selected from one or more of poly (9,9-dioctyl fluorene-CO—N-(4-butylphenyl) diphenylamine), polyvinyl carbazole, poly (N,N′-bis (4-butylphenyl)-N,N′-bis (phenyl) benzidine), poly (9,9-dioctylfluorene-co-bis-N,N-phenyl-1,4-phenylenediamine), 4,4′,4′-tris (carbazole-9-yl) triphenylamine, 4,4′-bis (9-carbazole) biphenyl, N,N′-diphenyl-N,N′-bis (3-methylphenyl)-1,1′-biphenyl-4,4′-diamine, N,N′-diphenyl-N,N′-(1-naphthyl)-1,1′-biphenyl-4,4′-diamine, poly (3,4-ethylenedioxythiophene)-poly (styrene sulfonic acid).

A material of the hole injection layer is selected from one or more of poly (3,4-ethylenedioxythiophene)-poly (styrene sulfonic acid), copper phthalocyanine, titanium phthalocyanine, 4,4′,4′-tri (N-3-methylphenyl-N-phenylamino) triphenylamine, 4,4′,4″-tris [2-naphthyl (phenyl) amino] triphenylamine, transition metal oxide and transition metal chalcogenide

A material of the anode is selected from one or more of metallic material, carbon-silicon material and metal oxide.

The present disclosure provides a preparation method of a photoelectric device includes the following steps.

Providing a first substrate, and the first substrate includes a first electrode.

Providing a film-forming solution, wherein the film-forming solution includes an electronic functional material and a crosslinking agent, and the crosslinking agent is selected from the azide compound above-mentioned.

Depositing the film-forming solution on the first substrate, and irradiating the film-forming solution with ultraviolet light to form an electronic functional layer.

Forming a second electrode on the electronic functional layer to obtain a photoelectric device.

Alternatively, the first substrate includes an anode and a luminescent layer which are stacked; depositing the film-forming solution on one side of the luminescent layer far away from the anode to form the electronic functional layer; and forming a cathode on the electronic functional layer to obtain a photoelectric device.

Alternatively, the film-forming solution includes a first film-forming solution and a second film-forming solution, and the formation of the electronic functional layer including: depositing the first film-forming solution on the luminescent layer, and irradiating the first film-forming solution with ultraviolet light to form a first film layer; and depositing the second film-forming solution on the first film layer, and irradiating the second film-forming solution with ultraviolet light to form a second film layer.

A material of the first film layer includes a first electronic functional material crosslinked by a first crosslinking agent, and the first electronic functional material is a doped metal oxide, and a doping element of the first electronic functional material is selected from one or more of Ga, Li, Al, Ag, In and Cd; a material of the second film layer includes a second electronic functional material crosslinked by a second crosslinking agent, and the second electronic functional material is a doped or undoped metal oxide, and a doping element of the second electronic functional material is selected from one or more of Mg and halogen elements.

Alternatively, the first substrate includes a cathode; depositing the film-forming solution on the cathode to form the electronic functional layer; and forming a luminescent layer and an anode on the electronic functional layer to obtain the photoelectric device.

Alternatively, the film-forming solution includes a first film-forming solution and a second film-forming solution, and the formation of the electronic functional layer including: depositing the second film-forming solution on the cathode, and irradiating the second film-forming solution with ultraviolet light to form a second film layer; and depositing the first film-forming solution on the second film layer, and irradiating the first film-forming solution with ultraviolet light to form a first film layer.

A material of the first film layer includes a first electronic functional material crosslinked by a first crosslinking agent, and the first electronic functional material is a doped metal oxide, and a doping element of the first electronic functional material is selected from one or more of Ga, Li, Al, Ag, In and Cd; a material of the second film layer includes a second electronic functional material crosslinked by a second crosslinking agent, and the second electronic functional material is a doped or undoped metal oxide, and a doping element of the second electronic functional material is selected from one or more of Mg and halogen elements.

Alternatively, the second film-forming solution further includes an auxiliary electronic functional material, and the auxiliary electronic functional material is selected from one or more of graphene, C60 and MoS₂.

A mass ratio of the first crosslinking agent in the material of the first film layer is 1%-10%.

A mass ratio of the second crosslinking agent in the material of the second film layer is 1%-10%.

In this present disclosure, the electron transport material is crosslinked by azide compound, which could form a stable crosslinked network. Under the action of the electron transport material and azide compound, the formed electronic functional layer has high stability, and the electronic functional layer could withstand the washing of the solvent brought by the preparation of the upper structural layer, thus avoiding the damage of its own structural layer. At the same time, the electronic functional layer also has good electronic transmission performance. In addition, the introduction of azide compound could also passivate the surface of electronic functional material and modify the defects of electronic functional material, thus improving the efficiency and life of photoelectric device.

### BRIEF DESCRIPTION OF DRAWINGS

In order to more clearly explain the technical solutions in the embodiments of the present disclosure, the following will briefly introduce the drawings required in the description of the embodiments. Obviously, the drawings in the following description are only some embodiments of the present disclosure. For those skilled in the art, without paying any creative work, other drawings can be obtained based on these drawings.

FIG. 1 is a schematic diagram of the structure of a photoelectric device according to an embodiment of the present disclosure.

FIG. 2 is a schematic diagram of the structure of a photoelectric device according to another embodiment of the present disclosure.

FIG. 3 is a schematic diagram of the structure of a photoelectric device according to another embodiment of the present disclosure.

FIG. 4 is a flowchart of a method for preparing a photoelectric device according to an embodiment of the present disclosure.

FIG. 5 is a schematic diagram of a surface-attached ligand of ZnO in Example 1 of the present disclosure.

FIG. 6 is a schematic diagram of cross-linking between the cross-linking agent and ZnO with ligand attached to its surface in Example 1 of the present disclosure.

In which, the reference numeral indicates:
anode 10; electronic functional layer 20; first film layer 201; second film layer 202; cathode 30; light emitting layer 40; hole functional layer 50.

### DETAILED DESCRIPTION

Technical solutions in embodiments of the present disclosure will be clearly and completely described below in conjunction with drawings in the embodiments of the present disclosure. Obviously, the described embodiments are only a part of embodiments of the present disclosure, rather than all the embodiments. Based on the embodiments in the present disclosure, all other embodiments obtained by those skilled in the art without creative work fall within the protection scope of the present disclosure.

The embodiment of the present disclosure provides a photoelectric device, and a photoelectric device and a preparation method therefor. The following are described in detail. It should be noted that the description order of the following embodiments is not taken as a limitation to the preferred order of the embodiments. In addition, in the description of the present disclosure, the term “comprising/including” means “comprising/including but not limited to”. The terms “first, second, third, etc”. are only used as signs and do not impose numerical requirements or establish order.

In the present disclosure, the term “and/or” is used to describe the association of associated objects, and means that there may be three relationships, for example, “A and/or B” may refer to three cases: the first case refers to the presence of A alone; the second case refers to the presence of both A and B; the third case refers to the presence of B alone, where A and B may be singular or plural.

In the present disclosure, the term “at least one” refers to one or more, and “a plurality of/multiple” refers to two or more. The terms “at least one”, “at least one of the followings”, or the like, refer to any combination of the items listed, including any combination of the singular or the plural items. For example, “at least one of a, b, or c” or “at least one of a, b, and c” may refer to: a, b, c, a-b (i.e., a and b), a-c, b-c, or a-b-c, where a, b, and c may be single or plural.

Additionally, in the description of the present disclosure, various embodiments of the present disclosure may be presented in a form of range. It should be understood that the description in the form of range is merely for convenience and brevity, and should not be construed as a hard limitation on the scope of the disclosure. Accordingly, it should be considered that the recited range description has specifically disclosed all possible subranges, as well as a single numerical value within that range. For example, it should be considered that a description of a range from 1 to 6 has specifically disclosed subranges, such as from 1 to 3, from 1 to 4, from 1 to 5, from 2 to 4, from 2 to 6, from 3 to 6, etc., and a single number within the range, such as 1, 2, 3, 4, 5, and 6, regardless of the range. Whenever a range of values is indicated herein, it is meant to include any recited number (fraction or integer) within the indicated range.

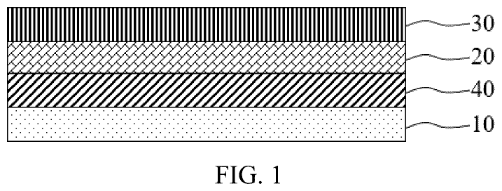

The first aspect, referring to FIG. 1, the present disclosure discloses a photoelectric device. The photoelectric device includes a cathode 30; an anode 10; and a functional layer, located between the cathode 30 the anode 10; wherein the functional layer includes an electronic functional layer 20, and a material of the electronic functional layer 20 includes an electronic functional material crosslinked by a crosslinking agent, and the crosslinking agent includes an azide compound which has at least two azide groups as terminal groups.

Because the azide compound has at least two azide groups (—N₃) as terminal groups, that is, the functionality of the azide compound is greater than or equal to 2, the azide compound could crosslink the electronic functional material, form a crosslinking network among the electronic functional material, and further form a stable electronic functional layer 20, thereby improving the solvent resistance of the electronic functional layer 20. It could be understood that the azide compound could have two azide groups as terminal groups, and could also have more than two azide groups as terminal groups. For example, in some embodiments, the azide compound might have three azide groups as terminal groups. In some embodiments, the azide compound has two azide groups as terminal groups, so that agglomeration of electronic functional material could be avoided. It should be noted that the terminal group here refers to the group at the end of the molecular chain of the azide compound, and the end here could be the end of a straight chain or the end of a branched chain.

In some embodiments, a general formula of the azide compound is N₃—R₂—R₁—R₃—N₃, wherein R₁ is a linking group which is selected from one or more of substituted or unsubstituted —(CH₂)ₘ₁—, —(CH₂)ₘ₂CH═CH(CH₂)ₘ₃—, —(CH₂)ₘ₄C≡C(CH₂)ₘ₅—, —(CH₂)ₘ₆O(CH₂)ₘ₇—, —(CH₂)ₘ₈CO(CH₂)ₘ₉—, —(CH₂)ₘ₁₀NHCO(CH₂)ₘ₁₁—, —(CH₂)ₘ₁₂CONH(CH₂)ₘ₁₃—, (CH₂)ₘ₁₄OCO(CH₂)ₘ₁₅—, —(CH₂)ₘ₁₆COO(CH₂)ₘ₁₇—, —(CH₂)ₘ₁₈(OCH₂)ₘ₁₉— and —COO(CH₂)ₘ₂₀OOC—, and m₁-m₂₀ are independently selected from an integer of 1-20. Further, m₁-m₁₈ could be independently selected from an integer of 1-15, an integer of 1-10, an integer of 1-5, and an integer of 1-3. The C1-C10 alkyl group could be selected from but not limited to one or more of methyl, ethyl, propyl, n-butyl, isopropyl, tert-butyl, —(CH₂)₄—CH₃, —(CH₂)₅—CH₃, —(CH₂)₆—CH₃ and the above alkyl derivatives. The C1-C10 alkoxy could be selected from but not limited to one or more of methoxy, ethoxy, propoxy, butoxy and the above alkoxy derivatives. The C1-C10 alkylthio could be selected from but not limited to one or more of methylthio, ethylthio, propylthio, butylthio and the above alkylthio derivatives.

In some embodiments, m₁-m₂₀ could each be independently selected from an integer of 1-10. Specifically, m₁-m₂₀ are each independently selected from an integer of 1-10, an integer of 1-8, an integer of 1-5, an integer of 1-3, etc.

In some embodiments, R₁ could be selected from one of —(CH₂)ₙ—, —CH₂CH═CH—, —CH₂C≡C—, —CH₂OCH₂—, —CH₂COCH₂—, —CH₂NHCOCH₂—, —CH₂OCOCH₂—, wherein a value range of n is 1-3.

R₂ and R₃ are independently selected from one of substituted or unsubstituted aromatic ring and substituted or unsubstituted heteroaromatic ring, wherein the heteroaromatic ring includes at least one heteroatom, and the heteroatom is selected from one or more of N, O and S; ring atoms of the aromatic ring include 6-30 C atoms, and ring atoms of the heteroaromatic ring include 1-25 C atoms.

Further, a substituent of R₂ and R₃ could be selected from one or more of nitro, cyano, carboxyl, halogen atom, hydroxyl, phenyl, vinyl, C1-C10 alkyl, C1-C10 alkoxy and C1-C10 alkylthio.

In other embodiments, a general formula of the azide compound is N₃—R₄—N₃, and R₄ is selected from one of substituted or unsubstituted saturated hydrocarbon groups with 2-30 C atoms and substituted or unsubstituted unsaturated hydrocarbon groups with 4-30 C atoms.

Further, a substituent of R₄ could be selected from one or more of nitro, cyano, carboxyl, halogen atom, hydroxyl, phenyl, vinyl, C1-C10 alkyl, C1-C10 alkoxy and C1-C10 alkylthio.

Further, the C1-C10 alkyl group could be selected from but not limited to one or more of methyl, ethyl, propyl, n-butyl, isopropyl, tert-butyl, —(CH₂)₄—CH₃, —(CH₂)₅—CH₃, —(CH₂)₆—CH₃ and the above alkyl derivatives. The C1-C10 alkoxy could be selected from but not limited to one or more of methoxy, ethoxy, propoxy, butoxy and the above alkoxy derivatives. The C1-C10 alkylthio could be selected from but not limited to one or more of methylthio, ethylthio, propylthio, butylthio and the above alkylthio derivatives.

In some embodiments, R₄ is selected from one of —(CH₂)ₙ₁—, —(CH₂)ₙ₂CH═CH(CH₂)ₙ₃—, wherein n₁-n₃ are independently selected from an integer of 6-20.

In some embodiments, R₄ is selected from one of substituted or unsubstituted saturated hydrocarbon groups with 6-30 C atoms and substituted or unsubstituted unsaturated hydrocarbon groups with 6-30 C atoms.

Further, R₄ could be selected from saturated hydrocarbon groups with 6-10 C atoms, R₄ could also be selected from saturated hydrocarbon groups with 6-15 C atoms, and R₄ could also be selected from saturated hydrocarbon groups with 6-20 C atoms. Specifically, R₄ is selected from one of —(CH₂)₆—, —(CH₂)₇—, —(CH₂)₈—, —(CH₂)₉—, —(CH₂)₁₀—, —(CH₂)₁₁—, —(CH₂)₁₂—, —(CH₂)₁₃—, —(CH₂)₁₄—, —(CH₂)₁₅—, —(CH₂)₁₆—, —(CH₂)₁₇—, —(CH₂)₁₈—, —(CH₂)₁₉—, —(CH₂)₂₀—.

Further, R₄ could be selected from unsaturated hydrocarbon groups with 6-10 C atoms, R₄ could also be selected from unsaturated hydrocarbon groups with 6-15 C atoms, and R₄ could also be selected from unsaturated hydrocarbon groups with 6-20 C atoms. Specifically, R₄ is selected from one of —(CH₂)₂CH═CH(CH₂)₂—, —(CH₂)₂CH═CH(CH₂)₃—, —(CH₂)₃CH═CH(CH₂)₃—, —(CH₂)₄CH═CH(CH₂)₄—, —(CH₂)₄CH═CH(CH₂)₅—, —(CH₂)₅CH═CH(CH₂)₅—, —(CH₂)₂C≡C(CH₂)₂—, —(CH₂)₂C≡C(CH₂)₃—, —(CH₂)₃C≡C(CH₂)₃—, —(CH₂)₃C≡C(CH₂)₄—, —(CH₂)₄C≡C(CH₂)₄—, —(CH₂)₄C≡C(CH₂)₅—, —(CH₂)₅C≡C(CH₂)₅—.

In some embodiments, the aromatic ring could be selected from one of benzene ring, naphthalene ring, anthracene ring and phenanthrene ring.

In some embodiments, the aromatic ring could be selected from benzene ring.

In some embodiments, the heteroaromatic ring is selected from one or more of thiophene ring, benzothiophene ring, isobenzothiophene ring, dibenzothiophene ring, pyrrole ring, indole ring, isoindole ring, pyridine ring, quinoline ring, benzo-5,6-quinoline ring, benzo-6,7-quinoline ring, benzo-7,8-quinoline ring, isoquinoline ring, acridine ring, phenazine ring, phenothiazine ring, phenazine ring, pyrazine ring, indazine ring, pyridazine ring, benzopyridazine ring, 1,3,5-triazine ring, 1,2,4-triazine ring, 1,2,3-triazine ring, 1,2,4,5-tetrazine ring, 1,2,3,4-tetrazine ring, 1,2,3,5-tetrazine ring, carbazole ring, azacarbazole ring, benzocarboline ring, pyrazole ring, indazole ring, oxazole ring, isoxazole ring, imidazole ring, benzimidazole ring, naphthoxazoline ring, phenimidazole ring, pyridoimidazole ring, pyrazinimidazole ring, quinoxaline imidazole ring, 1,2,3-triazole ring, 1,2,4-triazole ring, tetrazole ring, isoxazole ring, benzotriazole ring, 1,2,3-oxadiazole ring, 1,2,4-oxadiazole ring, 1,2,5-oxadiazole ring, 1,3,4-oxadiazole ring, benzoxazole ring, naphthoxazole ring, anthracazole ring, phenazole ring, 1,2-thiazole ring, 1,3-thiazole ring, benzothiazole ring, 1,2,3-thiadiazole ring, 1,2,4-thiadiazole ring, 1,2,5-thiadiazole ring, 1,3,4-thiadiazole ring, benzothiadiazole ring, pyrimidine ring, benzopyrimidine ring, naphthyridine ring, pteridine ring, quinoxaline ring, phenanthroline ring and purine ring.

In some embodiments, the azide compound could be selected from one or more compound having the following structural formula:

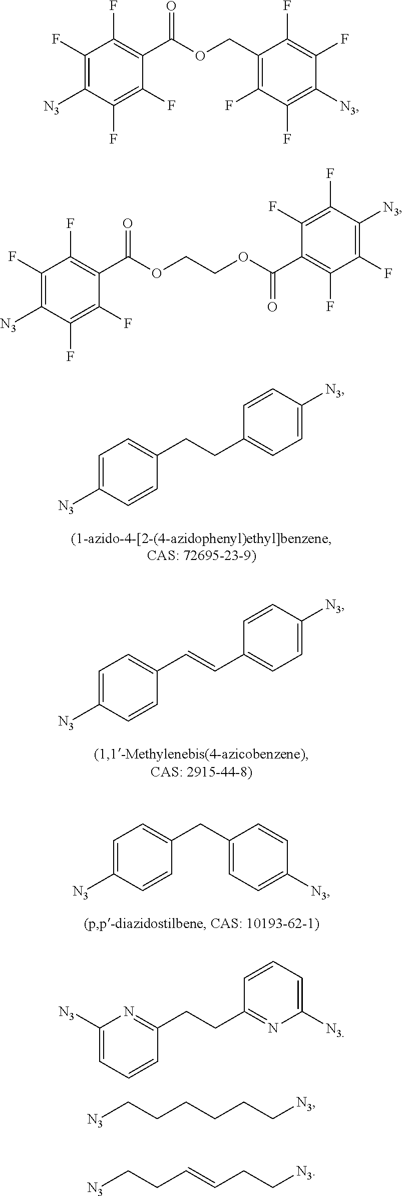

In some embodiments, a surface of the electronic functional material is connected with a ligand, and the crosslinking agent crosslinks the electronic functional material through the ligand. The ligand is selected from one or more of substituted or unsubstituted alcohol (R₅—OH) with 1-20 C atoms, substituted or unsubstituted mercaptan (R₆—SH) with 1-20 C atoms, substituted or unsubstituted carboxylic acid (R₇—COOH) with 1-20 C atoms, substituted or unsubstituted phosphonic acid with 1-20 C atoms (such as alkyl phosphonic acid R₈P(O)(OH)₂ and dialkyl phosphonic acid R₉R₁₀P(O)OH), and substituted or unsubstituted amines (R₁₁—NH₂) with 1-20 C atoms.

It should be noted that R₅-R₁₁ could be an alkyl group with 1-20 C atoms and an unsaturated hydrocarbon group with 1-20 C atoms, and R₅-R₁₁ could be a straight chain structure or a branched chain structure. In some embodiments, R₅-R₁₁ is selected from alkyl group with 10-20 C atoms and unsaturated hydrocarbon group with 10-20 C atoms.

Specifically, R₅-R₁₁ could be independently selected from one of CH₃(CH₂)₉—, CH₃(CH₂)₁₁—, CH₃(CH₂)₁₂—, CH₃(CH₂)₁₃—, CH₃(CH₂)₁₄—, CH₃(CH₂)₁₅—, CH₃(CH₂)₁₆—, CH₃(CH₂)₁₇—, CH₃(CH₂)₁₈—, CH₃(CH₂)₁₉—, CH₃(CH₂)₂₀—, CH₃(CH₂)₉CH═CH(CH₂)₂—, CH₃(CH₂)₁₀CH═CH(CH₂)₃—, CH₃(CH₂)₁₂CH═CH(CH₂)₃—, CH₃(CH₂)₉C≡C(CH₂)₂—, CH₃(CH₂)₁₀C≡C(CH₂)₃—, CH₃(CH₂)₁₂C≡C(CH₂)₃—.

When R₅-R₁₁ are substituted group, a substituent of R₅-R₁₁ could be selected from one or more of nitro, cyano, carboxyl, halogen atom, hydroxyl, phenyl, vinyl, C1-C10 alkyl, C1-C10 alkoxy and C1-C10 alkylthio.

In some embodiments, the ligands of the electronic functional material could be acids containing eighteen carbon atoms, such as oleic acid.

In some embodiments, the process of cross-linking the electronic functional material by the azide compound could be a process in which the azide groups in the azide compound react with alkyl chains of the ligand on the surface of the electronic functional material. Since the azide compound has at least two azide groups as terminal groups, each azide compound could react with at least two ligands on the surface of the electronic functional material, so as to cross-link the electronic functional material.

In some embodiments, the azide compound has two azide groups as terminal groups. At this time, one azide group could react with a ligand (the first ligand) on the surface of one electronic functional material, and the other group can react with a ligand (the second ligand) on the surface of another electronic functional material, so as to realize the crosslinking of two electronic functional materials.

Further, a reaction site of the azide group and the ligand could be any position of ligand molecular chain.

In some embodiments, the electronic functional material could be selected from doped or undoped metal oxide, wherein a doping element of the electronic functional material could be selected from one or more of Mg, Ca, Li, Ga, Al, Co, Mn, Ag, In, Cd and halogen elements. Further, the metal oxide could be selected from but not limited to one or more of ZnO, NiO, W₂O₃, Mo₂O₃, TiO₂, SnO, ZrO₂, Ta₂O₃, Ga₂O₃, SiO₂, Al₂O₃, CaO, HfO₂, SrTiO₃, BaTiO₃, MgTiO₃. In some embodiments, the electronic functional material could also be other materials with electron injection ability and/or electron transport ability with ligands attached to their surfaces, which is not limited here.

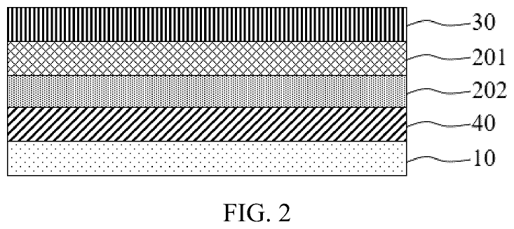

In some embodiments, referring to FIG. 2, the electronic functional layer 20 includes at least two layers stacked film layer.

As the electronic functional material in the electronic functional layer 20 is crosslinked under the action of the azide compound, good solvent resistance is obtained, so when other film layer is formed on the electronic functional layer 20 by the solvent method, the electronic functional layer 20 is stable. Based on this, the electronic functional layer 20 could be prepared by a solution method to a composite film layer including at least two layers stacked film layer.

In some embodiments, the electronic functional layer 20 could be a composite film layer including two layers stacked. The electronic functional layer 20 could also be a composite film layer including three layers, four layers or more.

In some embodiments, the composite film layer includes a first film layer 201 and a second film layer 202, and the second film layer 202 is arranged on the side of the first film layer 201 far away from the cathode 30.

A material of the first film layer 201 includes a first electronic functional material crosslinked by a first crosslinking agent, and the first electronic functional material is a doped metal oxide, and a doping element of the first electronic functional material is selected from one or more of Ga, Li, Al, Ag, In and Cd. A material of the second film layer 202 includes a second electronic functional material crosslinked by a second crosslinking agent, and the second electronic functional material is a doped or undoped metal oxide, and a doping element of the second electronic functional material is selected from one or more of Mg and halogen elements. The first crosslinking agent and the second crosslinking agent each independently include an azide compound which has at least two azide groups as terminal groups.

In some embodiments, a material of the second film layer 202 could also include an auxiliary electronic functional material, and the auxiliary electronic functional material could be selected from one or more of graphene, C60 and MoS₂.

In some embodiments, the first film layer 201 could be arranged adjacent to the cathode 30 with a higher work function. At this time, based on the selection of the first electronic functional material, the first electronic functional material could make the work function of the first film layer 201 more match that of the cathode 30, so as to achieve the effects of adjusting the work function of the electronic functional layer 20, reducing the electron injection barrier and improving the electron injection. The selection of doping element of the second electronic functional material in the second film layer 202 and the auxiliary electronic functional material could improve the electron transport capability of the second film layer 202. Therefore, when the work function of the cathode 30 is high, the arrangement of the stacked first film layer 201 and the stacked second film layer 202 could improve the electron injection capability and electron transmission capability of the photoelectric device, balance the transmission of carriers in the photoelectric device, and further achieve the effect of improving the service life and stability of the photoelectric device.

Further, the first crosslinking agent and the second crosslinking agent could be selected from the same crosslinking agent or different crosslinking agent.

In some embodiments, a mass ratio of the first crosslinking agent in the material of the first film layer 201 could be 1%-10%. In some embodiments, a mass ratio of the first crosslinking agent in the material of the first film layer 201 could be 2%-5%.

In some embodiments, a mass ratio of the second crosslinking agent in the material of the second film layer 202 could be 1%-10%. In some embodiments, a mass ratio of the second crosslinking agent in the material of the second film layer 202 could be 2%-5%.

In some embodiments, the photoelectric device is one of an upright structure photoelectric device and an inverted structure photoelectric device.

In some embodiments, the electronic functional material in the photoelectric device could be selected from materials sensitive to water and oxygen such as ZnO, TiO₂, LiF, etc. In this case, the photoelectric device is an inverted structure. In this way, the electronic functional material sensitive to water and oxygen could avoid reactions with water and oxygen in the environment, thereby improving the life and stability of photoelectric devices.

In some embodiments, a material of the cathode 30 of the photoelectric device with the inverted structure could be the same as that of the anode 10 of the photoelectric device with the upright structure. At this time, the electronic functional layer 20 might be set as a composite film layer including a first film layer 201 and a second film layer 202. In this way, the electron injection efficiency of the photoelectric device could be improved. The arrangement of the first film layer 201 and the second film layer 202 has been described above and will not be described here.

In some embodiments, the photoelectric device is one of a light emitting diode, a solar cell and a photodetector.

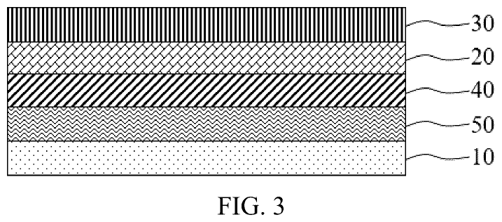

In some embodiments, please refer to FIG. 3, the photoelectric device is a luminescent diode, and the functional layer might also include a hole functional layer 50 and a luminescent layer 40. The hole functional layer 50 might include a hole transport layer and/or a hole injection layer. The hole functional layer 50 is disposed between the anode 10 and the luminescent layer 40, and the luminescent layer 40 is disposed between the hole functional layer 50 and the electronic functional layer 20, and the electronic functional layer 20 is disposed between the luminescent layer 40 and the cathode 30.

The electronic functional layer 20 includes an electron injection layer and/or an electron transport layer.

Further, the light emitting diode could be one of an organic light emitting diode (OLED), a quantum dot light emitting diode (QLED) and a micro light emitting diode (Micro LED).

In some embodiments, the light emitting diode could be a quantum dot light emitting diode having an inverted structure of a cathode 30, an electron transport layer, a quantum dot luminescent layer, a hole transport layer, a hole injection layer, and an anode 10 which are sequentially stacked.

A material of the cathode 30 could be selected from one or more of metallic material, carbon-silicon material and metal oxide. Further, the metallic material could be selected from one or more of Al, Ag, Cu, Mo, Au, Ba, Ca and Mg. The silicon-carbon material could be selected from one or more of silicon, graphite, carbon nanotube, graphene and carbon fiber. The metal oxide could be doped or undoped metal oxide, including but not limited to one or more of ITO, FTO, ATO, AZO, GZO, IZO, MZO and AMO. In some embodiments, the cathode could also be a composite electrode with metal sandwiched between doped or undoped transparent metal oxide, and the composite electrode could include but not limited to AZO/Ag/AZO, AZO/Al/AZO, ITO/Ag/ITO. The above expression of AZO/Ag/AZO indicates that there is Ag between AZOs. In some embodiments, the cathode 30 is ITO (indium tin oxide) with a thickness of 10-1000 nm.

The material of the electronic functional layer 20 has been described above, and will not be described here.

A material of the quantum dot luminescent layer could be selected from but not limited to one or more of silicon quantum dots, germanium quantum dots, cadmium sulfide quantum dots, cadmium selenide quantum dots, cadmium telluride quantum dots, zinc selenide quantum dots, lead sulfide quantum dots, lead selenide quantum dots, indium phosphide quantum dots, indium arsenide quantum dots and gallium nitride quantum dots. In some embodiments, a thickness of the quantum dot luminescent layer could be 20-50 nm.

A material of the hole transport layer could be selected from organic material with hole transport capability, and could be specifically selected from but not limited to one or more of poly (9,9-dioctyl fluorene-CO—N-(4-butylphenyl) diphenylamine) (TFB), polyvinyl carbazole (PVK), poly (N,N′-bis (4-butylphenyl)-N,N′-bis (phenyl) benzidine) (poly-TPD), poly (9,9-dioctylfluorene-co-bis-N,N-phenyl-1,4-phenylenediamine) (PFB), 4,4′, 4′-tris (carbazole-9-yl) triphenylamine (TCATA), 4,4′-bis (9-carbazole) biphenyl (CBP), N,N′-diphenyl-N,N′-bis (3-methylphenyl)-1,1′-biphenyl-4,4′-diamine (TPD), N,N′-diphenyl-N,N′-(1-naphthyl)-1,1′-biphenyl-4,4′-diamine (NPB), poly (3,4-ethylenedioxythiophene)-poly (styrene sulfonic acid) (PEDOT:PSS), Spiro-NPB, Spiro-TPD, doped graphene, undoped graphene and C60. A material of the hole transport layer could also be selected from inorganic material with hole transport capability, including but not limited to one or more of doped or undoped NiO, MoO₃, WO₃, V₂O₅, P-type gallium nitride, CrO₃ and CuO. In some embodiments, a thickness of the hole transport layer could be 20-100 nm.

A material of the hole injection layer could be selected from one or more of poly (3,4-ethylenedioxythiophene)-poly (styrene sulfonic acid) (PEDOT:PSS), copper phthalocyanine (CuPc), titanium phthalocyanine (TiOPc), 4,4′,4′-tri (N-3-methylphenyl-N-phenylamino) triphenylamine (m-MTDATA), 4,4′,4″-tris [2-naphthyl (phenyl) amino]triphenylamine (2-TNATA), transition metal oxide and transition metal chalcogenide. Among them, the transition metal oxide could be selected from one or more of NiOₓ, MoOₓ, WOₓ, CrOₓ and CuO; and the metal chalcogenide could be selected from one or more of MoS_{y}, MoSe_{y}, WS_{y}, WSe_{y} and CuS. A value of x and y in the aforementioned compounds could be determined according to the valence of atoms in the compounds. In some embodiments, a thickness of the hole injection layer could be 20-50 nm.

A material of the anode 10 could be selected from one or more of metallic material, carbon-silicon material and metal oxide. Further, the metallic material could be selected from one or more of Al, Ag, Cu, Mo, Au, Ba, Ca and Mg. The silicon-carbon material could be selected from one or more of silicon, graphite, carbon nanotube, graphene and carbon fiber. The metal oxide could be doped or undoped metal oxide, including but not limited to one or more of ITO, FTO, ATO, AZO, GZO, IZO, MZO and AMO. In some embodiments, the anode 10 could also be a composite electrode with metal sandwiched between doped or undoped transparent metal oxide, and the composite electrode could include but not limited to AZO/Ag/AZO, AZO/Al/AZO, ITO/Ag/ITO, ITO/Al/ITO, ZnO/Ag/ZnO, ZnO/Al/ZnO, TiO₂/Ag/TiO₂, TiO₂/Al/TiO₂, ZnS/Ag/ZnS, ZnS/Al/ZnS, TiO₂/Ag/TiO₂ and TiO₂/Al/TiO₂. In some embodiments, the anode 10 is Ag with a thickness of 10-1000 nm.

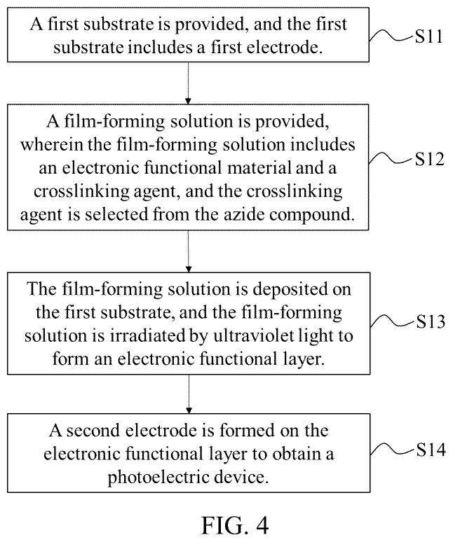

In the second aspect, please referring to FIG. 4, the present disclosure proposes a preparation method of a photoelectric device which includes step S11-S14.

In step S11, a first substrate is provided, and the first substrate includes a first electrode.

In step S12, a film-forming solution is provided, wherein the film-forming solution includes an electronic functional material and a crosslinking agent, and the crosslinking agent is selected from the azide compound above-mentioned.

In step S13, the film-forming solution is deposited on the first substrate, and the film-forming solution is irradiated by ultraviolet light to form an electronic functional layer 20.

In step S14, a second electrode is formed on the electronic functional layer 20 to obtain a photoelectric device.

In some embodiments, the photoelectric device is an upright photoelectric device, and the first substrate includes an anode 10 and a luminescent layer 40 which are stacked. The film-forming solution is deposited on one side of the luminescent layer 40 far away from the anode 10 to form the electronic functional layer 20. A cathode 30 is formed on the electronic functional layer 20 to obtain a photoelectric device.

In some embodiments, the first substrate further includes a hole functional layer 50, disposed between the anode 10 and the luminescent layer 40. The hole functional layer 50 includes a hole injection layer and/or a hole transport layer.

In some embodiments, the film-forming solution includes a first film-forming solution and a second film-forming solution, and the formation of the electronic functional layer 30 includes: the first film-forming solution is deposited on the luminescent layer 40, and the first film-forming solution is irradiated by ultraviolet light to form a first film layer 201; and the second film-forming solution is deposited on the first film layer 201, and the second film-forming solution is irradiated by ultraviolet light to form a second film layer 202.

A material of the first film layer 201 includes a first electronic functional material crosslinked by a first crosslinking agent, and the first electronic functional material is a doped metal oxide, and a doping element of the first electronic functional material is selected from one or more of Ga, Li, Al, Ag, In and Cd. A material of the second film layer 202 includes a second electronic functional material crosslinked by a second crosslinking agent, and the second electronic functional material is a doped or undoped metal oxide, and a doping element of the second electronic functional material is selected from one or more of Mg and halogen elements.

It should be noted that the photoelectric device prepared by this method is an upright photoelectric device. Further, functional layers such as a hole injection layer, a hole transport layer, a hole blocking layer could be provided between the anode 10 and the luminescent layer 40 of the first substrate. For example, in some embodiments, a hole injection layer and a hole transport layer could be sequentially stacked between the anode 10 and the luminescent layer 40 of the first substrate, wherein the hole injection layer is adjacent to the anode 10 and the hole transport layer is adjacent to the luminescent layer 40. It should be noted that the film-forming solution is deposited on the luminescent layer 40, and the word “on” is used in a broad sense. For example, in some embodiments, the luminescent layer 40 is also provided with an electron blocking layer, and the film-forming solution is actually deposited directly on the surface of the electron blocking layer, but it can still be regarded as deposited the film-forming solution on the luminescent layer 40.

In other embodiments, the photoelectric device is an inverted photoelectric device. The first substrate includes a cathode 30. The film-forming solution is disposed on the cathode 30 to form the electronic functional layer 20. A luminescent layer 40 and an anode 10 are sequentially formed on the electronic functional layer 20 to obtain the photoelectric device.

It should be noted that the photoelectric device prepared by this method is an inverted photoelectric device. The word “on” in the film-forming solution deposited on the cathode 30 is also in a broad sense. Further, after the electronic functional layer 30 is formed, film layers such as an electron blocking layer, a luminescent layer 40, a hole blocking layer, a hole transport layer, a hole injection layer, and an anode 10 could be formed on the electronic functional layer 30 to form a complete photoelectric device.

In some embodiments, the film-forming solution includes a first film-forming solution and a second film-forming solution, and the formation of the electronic functional layer 20 includes: the second film-forming solution is deposited on the cathode 30, and the second film-forming solution is irradiated by ultraviolet light to form a second film layer 202; and the first film-forming solution is deposited on the second film layer 202, and the first film-forming solution is irradiated by ultraviolet light to form a first film layer 201.

A material of the first film layer 201 includes a first electronic functional material crosslinked by a first crosslinking agent, and the first electronic functional material is a doped metal oxide, and a doping element of the first electronic functional material is selected from one or more of Ga, Li, Al, Ag, In and Cd. A material of the second film layer 202 includes a second electronic functional material crosslinked by a second crosslinking agent, and the second electronic functional material is a doped or undoped metal oxide, and a doping element of the second electronic functional material is selected from one or more of Mg and halogen elements.

In some embodiments, the film-forming solution could be deposited by spin coating or by inkjet printing, as long as the solution could be deposited, and there is no limitation here.

When preparing the photoelectric device, based on the photoactivity of azide groups, azide groups could form reactive nitro intermediates under ultraviolet irradiation, and further undergo insertion reaction with alkyl chains of ligand, thus crosslinking the electronic functional material.

In some embodiments, a wavelength of ultraviolet light could be 254-260 nm, such as 255 nm, 256 nm, 257 nm, 258 nm and 259 nm, etc. An energy density of ultraviolet light could be 0.1-4 mW/cm², such as 1 mW/cm², 2 mW/cm² and 3 mW/cm², etc. An irradiation time of ultraviolet light could be 2-8 s, such as 3 s, 4 s, 5 s, 6 s and 7 s, etc.

In some embodiments, the preparation method of the photoelectric device could further include processes such as annealing.

In some embodiments, the second film-forming solution further include an auxiliary electronic functional material, and the auxiliary electronic functional material could be selected from one or more of graphene, C60 and MoS₂.

In some embodiments, a mass ratio of the first crosslinking agent in the material of the first film layer 201 could be 1%-10%. In some embodiments, a mass ratio of the first crosslinking agent in the material of the first film layer 201 could be 2%-5%.

In some embodiments, a mass ratio of the second crosslinking agent in the material of the second film layer 202 could be 1%-10%. In some embodiments, a mass ratio of the second crosslinking agent in the material of the second film layer 202 could be 2%-5%.

When the mass ratio of crosslinking agent in solute is within the above range, it could avoid the defect state in the electronic functional material due to the existence of free radical.

### Example 1

This example provides a quantum dot light emitting diode with an inverted structure, which includes a cathode, an electron transport layer, a quantum dot luminescent layer, a hole transport layer, a hole injection layer and an anode which are sequentially stacked. The electron transport layer includes a first film layer and a second film layer which are stacked, and the second film layer is arranged on the side of the first film layer far from the cathode.

A material of the cathode is ITO and a thickness of the cathode is 100 nm.

A material of the first film layer includes a first transport material crosslinked by a first crosslinking agent, and the structural formula of the first crosslinking agent is as follows:

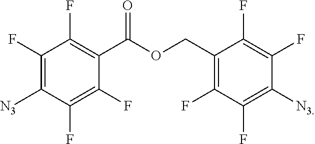 [SMILES: [N-]=[N+]=Nc1c(F)c(F)c(COC(=O)c2c(F)c(F)c(N=[N+]=[N-])c(F)c2F)c(F)c1F]

The first transport material is Ga-doped ZnO (ZnGaO), and the surface of ZnGaO is connected with oleic acid ligand. A thickness of the first film layer is 20 nm.

A material of the second film layer includes a second transport material crosslinked by a second crosslinking agent, and the second structural formula of the crosslinking agent is as follows:

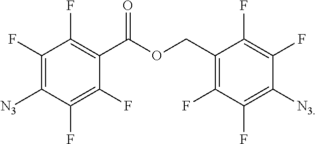 [SMILES: [N-]=[N+]=Nc1c(F)c(F)c(COC(=O)c2c(F)c(F)c(N=[N+]=[N-])c(F)c2F)c(F)c1F]

The second transport material is Mg-doped ZnO (ZnMgO), and the surface of ZnMgO is connected with oleic acid ligand. A thickness of the second film layer is 20 nm.

A material of the quantum dot luminescent layer is cadmium selenide blue luminescent layer quantum dots, and a thickness of the quantum dot luminescent layer is 30 mm.

A material of the hole transport layer is PVK, and a thickness of the hole transport layer is 20 nm.

A material of the hole injection layer is PEDOT:PSS, and a thickness of the hole injection layer is 50 nm.

A material of the anode is Ag, and a thickness of the anode is 100 nm.

This example also provides a preparation method of the quantum dot light emitting diode with an inverted structure includes steps S1-S13.

In step S1, a glass substrate is provided, and 100 nm ITO is deposited on the glass substrate to prepare a cathode.

In step S2, ZnGaO, a first cross-linking agent with structural formula

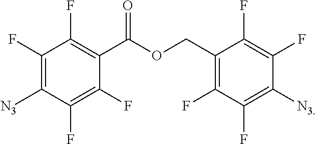 [SMILES: [N-]=[N+]=Nc1c(F)c(F)c(COC(=O)c2c(F)c(F)c(N=[N+]=[N-])c(F)c2F)c(F)c1F]

and ethanol are mixed to obtain a first film-forming solution, and a mass ratio of the first cross-linking agent in the solute of the first film-forming solution is 2%.

In step S3, the first film-forming solution is deposited on the cathode to form a first film with a thickness of 20 nm.

In step S4, ultraviolet light with wavelength of 254 nm and energy density of 4 mW/cm² is used to expose the first film for 5 s to obtain a first film layer.

In step S5, the glass substrate with the first film layer is soaked in toluene for 30 s, and then annealed at 100° C. for 10 min.

In step S6, ZnMgO, a second cross-linking agent with structural formula

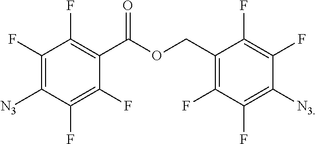 [SMILES: [N-]=[N+]=Nc1c(F)c(F)c(COC(=O)c2c(F)c(F)c(N=[N+]=[N-])c(F)c2F)c(F)c1F]

and ethanol are mixed to obtain a second film-forming solution, and a mass ratio of the second cross-linking agent in the solute of the second film-forming solution is 2%.

In step S7, the second film-forming solution is deposited on the first film layer to form a second film with a thickness of 20 nm.

In step S8, ultraviolet light with wavelength of 254 nm and energy density of 4 mW/cm² is used to expose the second film for 5 s to obtain a second film layer.

In step S9, the glass substrate with the second film layer is soaked in toluene for 30 s, and then annealed at 100° C. for 10 min.

In step S10, a quantum dot solution of cadmium selenide blue luminescent layer is deposited on the second film layer to form a quantum dot luminescent layer with a thickness of 30 nm.

In step S11, PVK is deposited on the quantum dot luminescent layer to form a hole transport layer with a thickness of 20 nm.

In step S12, PEDOT:PSS is deposited on the hole transport layer to form a hole injection layer with a thickness of 50 nm.

In step S13, Ag is deposited on the hole injection layer to form an anode with a thickness of 100 nm.

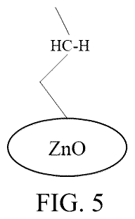

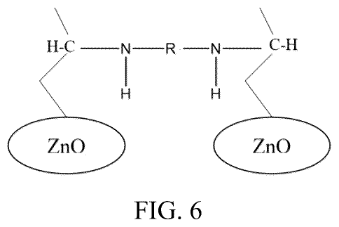

Refer to FIG. 5 for the schematic diagram of a surface-attached ligand of ZnO, and refer to FIG. 6 for the schematic diagram of cross-linking between the cross-linking agent and ZnO with ligand attached to its surface. In FIG. 6, the structural formula of R is

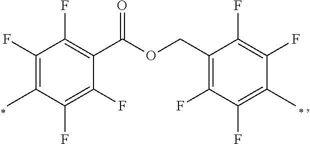 [SMILES: Cc1c(F)c(F)c(COC(=O)c2c(F)c(F)c(C)c(F)c2F)c(F)c1F]

wherein “*” represents the connection site with azide groups. It should be noted that FIG. 5 is only used to show the connection mode of ligand on ZnO, and the ligand structure shown in the figure is only a schematic, and does not refer to the actual structure of the ligands used. FIG. 6 is only used to illustrate the connection relationship between the crosslinking agent and the ligand, and does not limit the molecular structure of the crosslinking agent and the connection site between the ligand and the crosslinking agent.

### Example 2

This example provides a quantum dot light emitting diode with an inverted structure. The crosslinking agent in Example 1 is replaced by a crosslinking agent of CAS: 10193-62-1, and the remaining layer structures and materials are the same as those in the quantum dot light emitting diode provided in Example 1.

This example also provides a method for preparing an inverted structure quantum dot light emitting diode, which replaces the first crosslinking agent in step S2 of the preparation method provided in Example 1 with a crosslinking agent of CAS: 10193-62-1, and replaces the second crosslinking agent in step S6 of the preparation method provided in Example 1 with a crosslinking agent of CAS: 10193-62-1. The remaining steps are the same as those of the preparation method provided in Example 1.

The structural formula of CAS: 10193-62-1 is

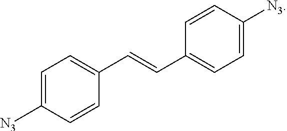 [SMILES: [N-]=[N+]=Nc1ccc(/C=C/c2ccc(N=[N+]=[N-])cc2)cc1]

### Example 3

This example provides a quantum dot light emitting diode with an inverted structure. The crosslinking agent in Example 1 is replaced by a crosslinking agent of

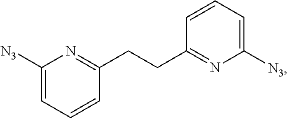 [SMILES: [N-]=[N+]=Nc1cccc(CCc2cccc(N=[N+]=[N-])n2)n1]

and the remaining layer structures and materials are the same as those in the quantum dot light emitting diode provided in Example 1.

This example also provides a method for preparing an inverted structure quantum dot light emitting diode, which replaces the first crosslinking agent in step S2 of the preparation method provided in Example 1 with a crosslinking agent of

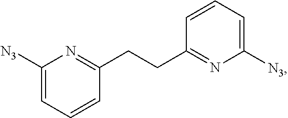 [SMILES: [N-]=[N+]=Nc1cccc(CCc2cccc(N=[N+]=[N-])n2)n1]

and replaces the second crosslinking agent in step S6 of the preparation method provided in Example 1 with a crosslinking agent of

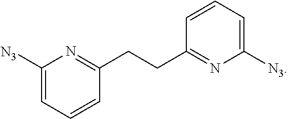 [SMILES: [N-]=[N+]=Nc1cccc(CCc2cccc(N=[N+]=[N-])n2)n1]

The remaining steps are the same as those of the preparation method provided in Example 1.

### Example 4

This example provides a quantum dot light emitting diode with an inverted structure. The crosslinking agent in Example 1 is replaced by a crosslinking agent of

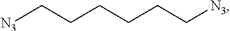 [SMILES: [N-]=[N+]=NCCCCCCN=[N+]=[N-]]

and the remaining layer structures and materials are the same as those in the quantum dot light emitting diode provided in Example 1.

This example also provides a method for preparing an inverted structure quantum dot light emitting diode, which replaces the first crosslinking agent in step S2 of the preparation method provided in Example 1 with a crosslinking agent of

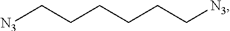 [SMILES: [N-]=[N+]=NCCCCCCN=[N+]=[N-]]

and replaces the second crosslinking agent in step S6 of the preparation method provided in Example 1 with a crosslinking agent of

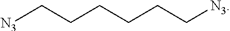 [SMILES: [N-]=[N+]=NCCCCCCN=[N+]=[N-]]

The remaining steps are the same as those of the preparation method provided in Example 1.

### Example 5

This example provides a quantum dot light emitting diode with an inverted structure. The crosslinking agent in Example 1 is replaced by a crosslinking agent of

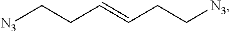 [SMILES: [N-]=[N+]=NCC/C=C/CCN=[N+]=[N-]]

and the remaining layer structures and materials are the same as those in the quantum dot light emitting diode provided in Example 1.

This example also provides a method for preparing an inverted structure quantum dot light emitting diode, which replaces the first crosslinking agent in step S2 of the preparation method provided in Example 1 with a crosslinking agent of

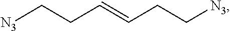 [SMILES: [N-]=[N+]=NCC/C=C/CCN=[N+]=[N-]]

and replaces the second crosslinking agent in step S6 of the preparation method provided in Example 1 with a crosslinking agent of

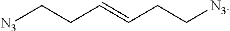 [SMILES: [N-]=[N+]=NCC/C=C/CCN=[N+]=[N-]]

The remaining steps are the same as those of the preparation method provided in Example 1.

### Example 6

This example provides an organic light emitting diode with an upright structure, which includes an anode, a hole injection layer, a hole transport layer, an organic luminescent layer, an electron transport layer and a cathode which are sequentially stacked.

The anode is a composite electrode, its material is ITO/Ag/ITO, and its thickness is 200 nm.

A material of the hole injection layer is m-MTDATA, and a thickness of the hole injection layer is 50 nm.

A material of the hole transport layer is TFB, and a thickness of the hole transport layer is 100 nm.

A material of the organic luminescent layer is Alq₃, and a thickness of the organic luminescent layer is 50 nm.

The electron transport layer includes a first film layer and a second film layer which are stacked, and the second film layer is arranged close to the luminescent layer.

A material of the second film layer includes a second transport material crosslinked by a second crosslinking agent, and the second structural formula of the crosslinking agent is as follows:

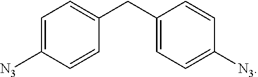 [SMILES: [N-]=[N+]=Nc1ccc(Cc2ccc(N=[N+]=[N-])cc2)cc1]

The second transport material is Mg-doped ZnO (ZnMgO), and the surface of ZnMgO is connected with oleic acid ligand. A thickness of the second film layer is 20 nm.

A material of the first film layer includes a first transport material crosslinked by a first crosslinking agent, and the structural formula of the first crosslinking agent is as follows:

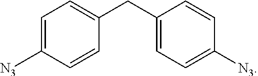 [SMILES: [N-]=[N+]=Nc1ccc(Cc2ccc(N=[N+]=[N-])cc2)cc1]

The first transport material is Ga-doped ZnO (ZnGaO), and the surface of ZnGaO is connected with oleic acid ligand. A thickness of the first film layer is 20 nm.

A material of the electron injection layer is LiF, and a thickness of the electron transport layer is 20 nm.

A material of the cathode is Al, and a thickness of the cathode is 100 nm.

This example also provides a preparation method of the organic light emitting diode with an upright structure includes steps S1-S9.

In step S1, an organic light emitting diode semi-finished product is provided, which includes a substrate, an anode, a hole injection layer, a hole transport layer and an organic luminescent layer which are sequentially stacked.

In step S2, ZnMgO, a cross-linking agent with structural formula

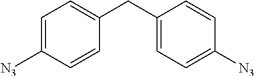 [SMILES: [N-]=[N+]=Nc1ccc(Cc2ccc(N=[N+]=[N-])cc2)cc1]

and propanol are mixed to obtain a second film-forming solution, and a mass ratio of the cross-linking agent in the solute of the second film-forming solution is 5%.

In step S3, the second film-forming solution is deposited on the organic luminescent layer to form a second film with a thickness of 20 nm.

In step S4, ultraviolet light with wavelength of 260 nm and energy density of 1 mW/cm² is used to expose the second film for 8 s to obtain a second film layer.

In step S5, ZnGaO, a first cross-linking agent with structural formula

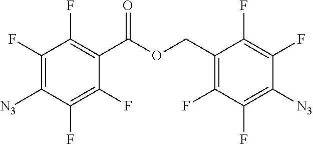 [SMILES: [N-]=[N+]=Nc1c(F)c(F)c(COC(=O)c2c(F)c(F)c(N=[N+]=[N-])c(F)c2F)c(F)c1F]

and ethanol are mixed to obtain a first film-forming solution, and a mass ratio of the first cross-linking agent in the solute of the first film-forming solution is 2%.

In step S6, the first film-forming solution is deposited on the second film layer to form a first film with a thickness of 20 nm.

In step S7, ultraviolet light with wavelength of 260 nm and energy density of 1 mW/cm² is used to expose the first film for 8 s to obtain a first film layer.

In step S8, the ethanol solution of LiF Is deposited on the first film layer to obtain an electron injection layer with a thickness of 20 nm.

In step S6, Al is evaporated on the electron injection layer to form a cathode with a thickness of 100 nm.

### Example 7

This example provides a quantum dot light emitting diode with an inverted structure, which includes a cathode, an electron transport layer, a quantum dot luminescent layer, a hole transport layer, a hole injection layer and an anode which are sequentially stacked. The electron transport layer includes a first film layer and a second film layer which are stacked, and the second film layer is arranged on the side of the first film layer far from the cathode.

A material of the cathode is ITO and a thickness of the cathode is 100 nm.

A material of the first film layer includes a first transport material crosslinked by a first crosslinking agent, and the structural formula of the first crosslinking agent is as follows:

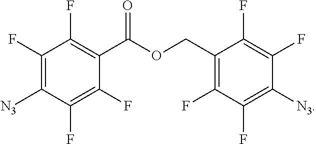 [SMILES: [N-]=[N+]=Nc1c(F)c(F)c(COC(=O)c2c(F)c(F)c(N=[N+]=[N-])c(F)c2F)c(F)c1F]

The first transport material is Ga-doped ZnO (ZnGaO), and the surface of ZnGaO is connected with oleic acid ligand. A thickness of the first film layer is 20 nm.

A material of the second film layer includes a second transport material crosslinked by a second crosslinking agent and auxiliary transmission material, and the second structural formula of the crosslinking agent is as follows:

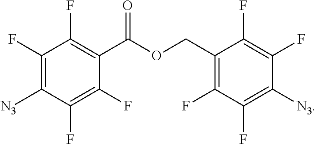 [SMILES: [N-]=[N+]=Nc1c(F)c(F)c(COC(=O)c2c(F)c(F)c(N=[N+]=[N-])c(F)c2F)c(F)c1F]

The second transport material is Mg-doped ZnO (ZnMgO), and the surface of ZnMgO is connected with oleic acid ligand. The auxiliary transmission material is graphene. A thickness of the second film layer is 20 nm.

A material of the quantum dot luminescent layer is cadmium selenide blue luminescent layer quantum dots, and a thickness of the quantum dot luminescent layer is 30 mm.

A material of the hole transport layer is PVK, and a thickness of the hole transport layer is 20 nm.

A material of the hole injection layer is PEDOT:PSS, and a thickness of the hole injection layer is 50 nm.

A material of the anode is Ag, and a thickness of the anode is 100 nm.

This example also provides a preparation method of the quantum dot light emitting diode with an inverted structure includes steps S1-S13.

In step S1, a glass substrate is provided, and 100 nm ITO is deposited on the glass substrate to prepare a cathode.

In step S2, ZnGaO, a first cross-linking agent with structural formula

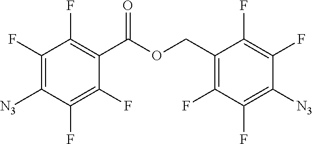 [SMILES: [N-]=[N+]=Nc1c(F)c(F)c(COC(=O)c2c(F)c(F)c(N=[N+]=[N-])c(F)c2F)c(F)c1F]

and ethanol are mixed to obtain a first film-forming solution, and a mass ratio of the first cross-linking agent in the solute of the first film-forming solution is 2%.

In step S3, the first film-forming solution is deposited on the cathode to form a first film with a thickness of 20 nm.

In step S4, ultraviolet light with wavelength of 254 nm and energy density of 4 mW/cm² is used to expose the first film for 5 s to obtain a first film layer.

In step S5, the glass substrate with the first film layer is soaked in toluene for 30 s, and then annealed at 100° C. for 10 min.

In step S6, ZnMgO, a second cross-linking agent with structural formula

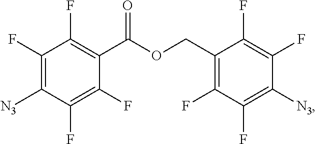 [SMILES: [N-]=[N+]=Nc1c(F)c(F)c(COC(=O)c2c(F)c(F)c(N=[N+]=[N-])c(F)c2F)c(F)c1F]

graphene and ethanol are mixed to obtain a second film-forming solution, and a mass ratio of the second cross-linking agent in the solute of the second film-forming solution is 2%.

In step S7, the second film-forming solution is deposited on the first film layer to form a second film with a thickness of 20 nm.

In step S8, ultraviolet light with wavelength of 254 nm and energy density of 4 mW/cm² is used to expose the second film for 5 s to obtain a second film layer.

In step S9, the glass substrate with the second film layer is soaked in toluene for 30 s, and then annealed at 100° C. for 10 min.

In step S10, a quantum dot solution of cadmium selenide blue luminescent layer is deposited on the second film layer to form a quantum dot luminescent layer with a thickness of 30 nm.

In step S11, PVK is deposited on the quantum dot luminescent layer to form a hole transport layer with a thickness of 20 nm.

In step S12, PEDOT:PSS is deposited on the hole transport layer to form a hole injection layer with a thickness of 50 nm.

In step S13, Ag is deposited on the hole injection layer to form an anode with a thickness of 100 nm.

### Example 8

This example provides a quantum dot light emitting diode with an inverted structure. The auxiliary transmission material in Example 7 is replaced by MoS₂, and the remaining layer structures and materials are the same as those in the quantum dot light emitting diode provided in Example 7.

This example also provides a method for preparing an inverted structure quantum dot light emitting diode, which replaces the auxiliary transmission material in step S6 of the preparation method provided in Example 7 with MoS₂. The remaining steps are the same as those of the preparation method provided in Example 7.

### Example 9

This example provides a quantum dot light emitting diode with an inverted structure. The auxiliary transmission material in Example 7 is replaced by MoS₂ and C60, and the remaining layer structures and materials are the same as those in the quantum dot light emitting diode provided in Example 7.

This example also provides a method for preparing an inverted structure quantum dot light emitting diode, which replaces the auxiliary transmission material in step S6 of the preparation method provided in Example 7 with MoS₂ and C60. The remaining steps are the same as those of the preparation method provided in Example 7.

### Comparative Example 1

This comparative example is different from Example 1 in that it does not use any crosslinking agent in the process of preparing the electron transport layer.

The performance of light emitting diodes in Examples 1-9 and Comparative Example 1 is tested, and the test results are shown in Table 1. Wherein EQE represents device efficiency; T95@1K nite represents the time taken for the brightness of light emitting diode to decay to 95% of the initial brightness under the brightness of 1000 nit, which is used to characterize the device life.

TABLE 1

| | Turn-on voltage (V) | EQE(%) | T95@1 Knite(h) |
|---|---|---|---|
| Example 1 | 1.65 | 14.8 | 45 |
| Example 2 | 1.57 | 15.5 | 49 |
| Example 3 | 1.80 | 15.0 | 40 |
| Example 4 | 1.78 | 14.8 | 40 |
| Example 5 | 1.63 | 15.8 | 50 |
| Example 6 | 1.92 | 12.5 | 42 |
| Example 7 | 1.67 | 15.2 | 42 |
| Example 8 | 1.70 | 14.8 | 46 |
| Example 9 | 1.69 | 14.5 | 43 |
| Comparative | 2.25 | 10.5 | 0 |
| Example 1 | | | |

From the results in Table 1, it could be seen that compared to the existing technology, the quantum dot light emitting diode provided by the present disclosure not only reduces the turn-on voltage, but also increases the device efficiency and life. The reason for this is that the electronic transport layer of the photoelectric device improved by the present disclosure has good solvent resistance, which could resist solvent erosion in the subsequent preparation process, and the film layer is stable, thereby improving the efficiency and life of the photoelectric device.

Photoelectric device and preparation method therefor are described in detail above. The principles and embodiments of the present disclosure have been described with reference to specific embodiments, and the description of the above embodiments is merely intended to aid in the understanding of the method of the present disclosure and its core idea. At the same time, changes may be made by those skilled in the art to both the specific implementations and the scope of present disclosure in accordance with the teachings of the present disclosure. In view of the foregoing, the content of the present specification should not be construed as limiting the disclosure.

1. A photoelectric device, comprising:
a cathode;
an anode; and
a functional layer, located between the cathode the anode; wherein the functional layer comprises an electronic functional layer, and a material of the electronic functional layer comprises an electronic functional material crosslinked by a crosslinking agent, and the crosslinking agent comprises an azide compound which has at least two azide groups as terminal groups.

2. The photoelectric device according to claim 1, wherein a general formula of the azide compound is N₃—R₂—R₁—R₃—N₃, wherein R₁ is a linking group which is selected from one or more of substituted or unsubstituted —(CH₂)ₘ₁—, —(CH₂)ₘ₂CH═CH(CH₂)ₘ₃—, —(CH₂)ₘ₄C≡C(CH₂)ₘ₅—, —(CH₂)ₘ₆O(CH₂)ₘ₇—, —(CH₂)ₘ₈CO(CH₂)ₘ₉—, —(CH₂)ₘ₁₀NHCO(CH₂)ₘ₁₁—, —(CH₂)ₘ₁₂CONH(CH₂)ₘ₁₃—, —(CH₂)ₘ₁₄OCO(CH₂)ₘ₁₅—, —(CH₂)ₘ₁₆COO(CH₂)ₘ₁₇—, —(CH₂)ₘ₁₈(OCH₂)ₘ₁₉— and —COO(CH₂)ₘ₂₀OOC—, and m₁-m₂₀ are independently selected from an integer of 1-20; and
R₂ and R₃ are independently selected from one of substituted or unsubstituted aromatic ring and substituted or unsubstituted heteroaromatic ring, wherein the heteroaromatic ring comprises at least one heteroatom, and the heteroatom is selected from one or more of N, O and S; ring atoms of the aromatic ring comprise 6-30 C atoms, and ring atoms of the heteroaromatic ring comprise 1-25 C atoms.

3. The photoelectric device according to claim 2, wherein m₁-m₂₀ are each independently selected from an integer of 1-10.

4. The photoelectric device according to claim 3, wherein R₁ is selected from one of —(CH₂)ₙ—, —CH₂CH═CH—, —CH₂C≡C—, —CH₂OCH₂—, —CH₂COCH₂—, —CH₂NHCOCH₂—, —CH₂OCOCH₂—, wherein a value range of n is 1-3.

5. The photoelectric device according to claim 2, wherein the aromatic ring is selected from one of benzene ring, naphthalene ring, anthracene ring and phenanthrene ring; and
the heteroaromatic ring is selected from one or more of thiophene ring, benzothiophene ring, isobenzothiophene ring, dibenzothiophene ring, pyrrole ring, indole ring, isoindole ring, pyridine ring, quinoline ring, benzo-5,6-quinoline ring, benzo-6,7-quinoline ring, benzo-7,8-quinoline ring, isoquinoline ring, acridine ring, phenazine ring, phenothiazine ring, phenazine ring, pyrazine ring, indazine ring, pyridazine ring, benzopyridazine ring, 1,3,5-triazine ring, 1,2,4-triazine ring, 1,2,3-triazine ring, 1,2,4,5-tetrazine ring, 1,2,3,4-tetrazine ring, 1,2,3,5-tetrazine ring, carbazole ring, azacarbazole ring, benzocarboline ring, pyrazole ring, indazole ring, oxazole ring, isoxazole ring, imidazole ring, benzimidazole ring, naphthoxazoline ring, phenimidazole ring, pyridoimidazole ring, pyrazinimidazole ring, quinoxaline imidazole ring, 1,2,3-triazole ring, 1,2,4-triazole ring, tetrazole ring, isoxazole ring, benzotriazole ring, 1,2,3-oxadiazole ring, 1,2,4-oxadiazole ring, 1,2,5-oxadiazole ring, 1,3,4-oxadiazole ring, benzoxazole ring, naphthoxazole ring, anthracazole ring, phenazole ring, 1,2-thiazole ring, 1,3-thiazole ring, benzothiazole ring, 1,2,3-thiadiazole ring, 1,2,4-thiadiazole ring, 1,2,5-thiadiazole ring, 1,3,4-thiadiazole ring, benzothiadiazole ring, pyrimidine ring, benzopyrimidine ring, naphthyridine ring, pteridine ring, quinoxaline ring, phenanthroline ring and purine ring.

6. The photoelectric device according to claim 1, wherein a general formula of the azide compound is N₃—R₄—N₃, and R₄ is selected from one of substituted or unsubstituted saturated hydrocarbon groups with 2-30 C atoms and substituted or unsubstituted unsaturated hydrocarbon groups with 4-30 C atoms; and
a substituent of R₄ is selected from one or more of nitro, cyano, carboxyl, halogen atom, hydroxyl, phenyl, vinyl, C1-C10 alkyl, C1-C10 alkoxy and C1-C10 alkylthio.

7. The photoelectric device according to claim 6, wherein R₄ is selected from one of substituted or unsubstituted saturated hydrocarbon groups with 6-30 C atoms and substituted or unsubstituted unsaturated hydrocarbon groups with 6-30 C atoms.

8. The photoelectric device according to claim 6, wherein R₄ is selected from one of —(CH₂)ₙ₁—, —(CH₂)ₙ₂CH═CH(CH₂)ₙ₃—, wherein n₁-n₃ are independently selected from an integer of 6-20.

9. The photoelectric device according to claim 1, wherein the azide compound is selected from one or more compound having the following structural formula:

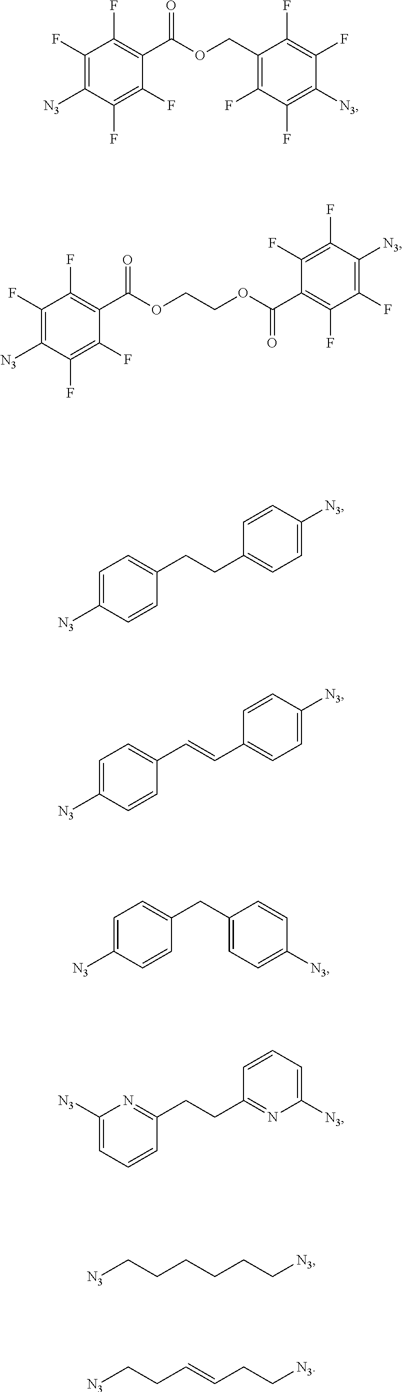

10. The photoelectric device according to claim 1, wherein a surface of the electronic functional material is connected with a ligand, and the crosslinking agent crosslinks the electronic functional material through the ligand; and the ligand is selected from one or more of substituted or unsubstituted alcohol with 1-20 C atoms, substituted or unsubstituted mercaptan with 1-20 C atoms, substituted or unsubstituted carboxylic acid with 1-20 C atoms, substituted or unsubstituted phosphonic acid with 1-20 C atoms, and substituted or unsubstituted amines with 1-20 C atoms; and
a substituent of the substituted ligand is selected from one or more of nitro, cyano, carboxyl, halogen atom, hydroxyl, phenyl, vinyl, C1-C10 alkyl, C1-C10 alkoxy and C1-C10 alkylthio.

11. The photoelectric device according to claim 1, wherein the electronic functional layer comprises a first film layer and a second film layer, and the second film layer is arranged on the side of the first film layer far away from the cathode;
a material of the first film layer comprises a first electronic functional material crosslinked by a first crosslinking agent, and the first electronic functional material is a doped metal oxide, and a doping element of the first electronic functional material is selected from one or more of Ga, Li, Al, Ag, In and Cd; a material of the second film layer comprises a second electronic functional material crosslinked by a second crosslinking agent, and the second electronic functional material is a doped or undoped metal oxide, and a doping element of the second electronic functional material is selected from one or more of Mg and halogen elements; and
the first crosslinking agent and the second crosslinking agent each independently comprise an azide compound which has at least two azide groups as terminal groups.

12. The photoelectric device according to claim 11, wherein a material of the second film layer also comprises an auxiliary electronic functional material, and the auxiliary electronic functional material is selected from one or more of graphene, C60 and MoS₂.

13. The photoelectric device according to claim 11, wherein a mass ratio of the first crosslinking agent in the material of the first film layer is 1%-10%; and
a mass ratio of the second crosslinking agent in the material of the second film layer is 1%-10%.

14. The photoelectric device according to claim 1, wherein the functional layer also comprises a hole functional layer and a luminescent layer; the hole functional layer comprises a hole transport layer and/or a hole injection layer; the hole functional layer is disposed between the anode and the luminescent layer, and the luminescent layer is disposed between the hole functional layer and the electronic functional layer, and the electronic functional layer is disposed between the luminescent layer and the cathode;
a material of the cathode is selected from one or more of metallic material, carbon-silicon material and metal oxide;
a material of the luminescent layer is selected from one or more of Si, Ge, CdSe, CdS, ZnSe, ZnS, CdTe, ZnTe, CdZnS, CdZnSe, CdZnTe, ZnSeS, ZnSeTe, ZnTeS, CdSeS, CdSeTe, CdTeS, CdZnSeS, CdZnSeTe, CdZnSTe, CdSeSTe, ZnSeSTe, CdZnSeSTe, CdSe/ZnS, CdZnSe/ZnS, CdS/CdZnS, InP, InAs, InAsP, InP/InAsP, PbS, PbSe, PbTe, PbSeS, PbSeTe, PbSTe, PbSe/PbS, GaN;
a material of the hole transport layer is selected from organic material with hole transport capability, and is specifically selected from one or more of poly (9,9-dioctyl fluorene-CO—N-(4-butylphenyl) diphenylamine), polyvinyl carbazole, poly (N,N′-bis (4-butylphenyl)-N,N′-bis (phenyl) benzidine), poly (9,9-dioctylfluorene-co-bis-N,N-phenyl-1,4-phenylenediamine), 4,4′,4′-tris (carbazole-9-yl) triphenylamine, 4,4′-bis (9-carbazole) biphenyl, N,N′-diphenyl-N,N′-bis (3-methylphenyl)-1,1′-biphenyl-4,4′-diamine, N,N′-diphenyl-N,N′-(1-naphthyl)-1,1′-biphenyl-4,4′-diamine, poly (3,4-ethylenedioxythiophene)-poly (styrene sulfonic acid);
a material of the hole injection layer is selected from one or more of poly (3,4-ethylenedioxythiophene)-poly (styrene sulfonic acid), copper phthalocyanine, titanium phthalocyanine, 4,4′,4′-tri (N-3-methylphenyl-N-phenylamino) triphenylamine, 4,4′,4″-tris [2-naphthyl (phenyl) amino] triphenylamine, transition metal oxide and transition metal chalcogenide; and
a material of the anode is selected from one or more of metallic material, carbon-silicon material and metal oxide.

15. A preparation method of a photoelectric device, comprising:
providing a first substrate, and the first substrate comprises a first electrode;
providing a film-forming solution, wherein the film-forming solution comprises an electronic functional material and a crosslinking agent, and the crosslinking agent comprises an azide compound which has at least two azide groups as terminal groups;
depositing the film-forming solution on the first substrate, and irradiating the film-forming solution with ultraviolet light to form an electronic functional layer; and
forming a second electrode on the electronic functional layer to obtain a photoelectric device.

16. The preparation method according to claim 15, wherein the first substrate comprises an anode and a luminescent layer which are stacked; depositing the film-forming solution on one side of the luminescent layer far away from the anode to form the electronic functional layer; and forming a cathode on the electronic functional layer to obtain a photoelectric device.

17. The preparation method according to claim 16, wherein the film-forming solution comprises a first film-forming solution and a second film-forming solution, and the formation of the electronic functional layer comprising:
depositing the first film-forming solution on the luminescent layer, and irradiating the first film-forming solution with ultraviolet light to form a first film layer; and depositing the second film-forming solution on the first film layer, and irradiating the second film-forming solution with ultraviolet light to form a second film layer; and
a material of the first film layer comprises a first electronic functional material crosslinked by a first crosslinking agent, and the first electronic functional material is a doped metal oxide, and a doping element of the first electronic functional material is selected from one or more of Ga, Li, Al, Ag, In and Cd; a material of the second film layer comprises a second electronic functional material crosslinked by a second crosslinking agent, and the second electronic functional material is a doped or undoped metal oxide, and a doping element of the second electronic functional material is selected from one or more of Mg and halogen elements.

18. The preparation method according to claim 15, wherein the first substrate comprises a cathode; depositing the film-forming solution on the cathode to form the electronic functional layer; and forming a luminescent layer and an anode on the electronic functional layer to obtain the photoelectric device.

19. The preparation method according to claim 18, wherein the film-forming solution comprises a first film-forming solution and a second film-forming solution, and the formation of the electronic functional layer comprising:
depositing the second film-forming solution on the cathode, and irradiating the second film-forming solution with ultraviolet light to form a second film layer; and depositing the first film-forming solution on the second film layer, and irradiating the first film-forming solution with ultraviolet light to form a first film layer; and
a material of the first film layer comprises a first electronic functional material crosslinked by a first crosslinking agent, and the first electronic functional material is a doped metal oxide, and a doping element of the first electronic functional material is selected from one or more of Ga, Li, Al, Ag, In and Cd; a material of the second film layer comprises a second electronic functional material crosslinked by a second crosslinking agent, and the second electronic functional material is a doped or undoped metal oxide, and a doping element of the second electronic functional material is selected from one or more of Mg and halogen elements.

20. The preparation method according to claim 19, wherein the second film-forming solution further comprises an auxiliary electronic functional material, and the auxiliary electronic functional material is selected from one or more of graphene, C60 and MoS₂;
a mass ratio of the first crosslinking agent in the material of the first film layer is 1%-10%; and
a mass ratio of the second crosslinking agent in the material of the second film layer is 1%-10%.
